(19) United States
(12) Patent Application Publication
(10) Pub. No.: US 2026/0066897 A1
(43) Pub. Date: Mar. 5, 2026

(54) SWITCHING CIRCUIT CAPABLE OF EFFECTIVELY REDUCING ON-RESISTANCE

(71) Applicant: Richtek Technology Corporation, Zhubei City (TW)

(72) Inventors: Li-Di Lo, Taichung (TW); Chien-Fu Tang, Hsinchu (TW)

(21) Appl. No.: 18/978,254

(22) Filed: Dec. 12, 2024

Related U.S. Application Data
(60) Provisional application No. 63/690,525, filed on Sep. 4, 2024.

(51) Int. Cl. H03K 17/687; H02M 1/088; H03K 17/567

(52) U.S. Cl. CPC H03K 17/6871; H02M 1/088; H03K 17/567

(57) ABSTRACT

A switching circuit includes a first transistor, which is a compound junction transistor; and a second transistor, which is an enhancement-type MOS transistor. The first transistor and the second transistor are connected in series between the first and second terminals of the switching circuit and are configured to control conduction and cutoff between these two ends. A first gate voltage is configured to control the gate of the first transistor; a second gate voltage is configured to control the gate of the second transistor. A level-shifting circuit is configured to generate the first gate voltage based on a voltage correlated with the second gate voltage.

### CROSS REFERENCE

The present invention claims priority to U.S. 63/690525 filed on Sep. 4, 2024 and to TW 113145358 filed on Nov. 25, 2024. The present invention relates to a switching circuit, and more particularly, to a switching circuit capable of effectively reducing on-resistance.

### DESCRIPTION OF RELATED ART

FIGS. 1A and 1B illustrate two prior art switching circuits. Switching circuit 200 includes an upper silicon carbide junction field-effect transistor (SiC JFET) M1 and a lower enhancement-mode MOS transistor M2, which are connected in series between a first terminal N1 and a second terminal N2 of the switching circuit 200. In FIG. 1A, the gate of transistor M1 is connected to the source of transistor M2, and the conduction state between terminals N1 and N2 is controlled by the gate voltage VG2 of transistor M2, which is coupled to the control terminal NC. The second terminal N2, for example, is connected to a ground potential.

Transistor M1 is a default-on device; therefore, when the gate-to-source voltage is 0, transistor M1 remains in the conducting state. Since the gate voltage VG1 of transistor M1 is directly provided by the source of transistor M2, the on-resistance of transistor M1 in this configuration is relatively high, resulting in a higher equivalent on-resistance of the switching circuit 200 and consequently greater power loss.

The circuit in FIG. 1B improves on this by introducing a fixed voltage VOS between the source of transistor M2 and the gate of transistor M1, thereby increasing the gate voltage of transistor M1 and reducing its on-resistance, which enhances the overall efficiency of the switch. However, in this prior art, the gate voltage of transistor M1 is approximately fixed at 15V to 25V, which also forces the drain voltage VD2 of transistor M2 to rise. This requires the use of a higher voltage-rated MOS transistor for transistor M2 to withstand the increased voltage, leading to higher costs and increased on-resistance.

In view of the above, the present invention addresses the deficiencies of the prior art by providing a switching circuit capable of effectively reducing on-resistance.

### SUMMARY OF THE INVENTION

In one perspective, the present invention provides a switching circuit comprising a first transistor, which is a compound junction transistor; a second transistor, which is an enhancement-mode MOS transistor; the first transistor and the second transistor being connected in series between a first terminal and a second terminal of the switching circuit for controlling conduction and cutoff between the first terminal and the second terminal; a first gate voltage for controlling a gate of the first transistor; a second gate voltage for controlling a gate of the second transistor; and a level-shifting circuit for generating the first gate voltage based on a pre-control voltage associated with the second gate voltage.

In one preferred embodiment, the breakdown voltage of the first transistor is higher than the breakdown voltage of the second transistor.

In one preferred embodiment, the switching circuit is configured in one of the following arrangements: arrangement A: when the second gate voltage is controlled to an enabled state, the level-shifting circuit shifts the pre-control voltage by a level-shift voltage to generate the first gate voltage; or arrangement B: when the second gate voltage is controlled to an enabled state, the level-shifting circuit switches the first gate voltage to a supply voltage based on the pre-control voltage, wherein the supply voltage is higher than a source voltage of the second transistor.

In one preferred embodiment, in arrangement A, the pre-control voltage corresponds to the source voltage of the second transistor, wherein the first gate voltage equals the source voltage of the second transistor plus the level-shift voltage; or the pre-control voltage corresponds to a drain voltage of the second transistor, wherein the first gate voltage equals the drain voltage plus the level-shift voltage.

In one preferred embodiment, in arrangement B, the pre-control voltage corresponds to the second gate voltage or to a drain voltage of the second transistor.

In one preferred embodiment, in an enabled state, the level of the second gate voltage is higher than the level of the first gate voltage.

In one preferred embodiment, in arrangement A, in the enabled state, a level of the level-shift voltage is lower than a gate-to-source forward conduction voltage of the first transistor; or in arrangement B, the supply voltage is less than the gate-to-source forward conduction voltage of the first transistor.

In one preferred embodiment, the first transistor is a silicon carbide junction field-effect transistor (SiC JFET).

In one preferred embodiment, the first transistor and the second transistor are both N-type or both P-type transistors.

In one preferred embodiment, in arrangement A, the level-shifting circuit further includes a first adjustment switch coupled between the source voltage of the second transistor and the first gate voltage, configured to switch based on the second gate voltage, wherein the first adjustment switch is off when the second gate voltage is in the enabled state and is on when the second gate voltage is in a disabled state.

In one preferred embodiment, in arrangement A, the level-shifting circuit further includes a RV source and a resistor connected in series between the source voltage of the second transistor and the first gate voltage; the RV source and a second adjustment switch connected in series between the source voltage of the second transistor and the first gate voltage, wherein the second adjustment switch operates inversely to the first adjustment switch; the RV source and a first diode connected in series between the source voltage of the second transistor and the first gate voltage; or a second diode biased by a current source and coupled between the source voltage of the second transistor and the first gate voltage; wherein the RV source provides the level-shift voltage, or the forward conduction voltage of the second diode corresponds to the level-shift voltage.

In one preferred embodiment, the switching circuit further comprises a Zener diode and a conversion transistor, wherein the Zener diode provides a pre-reference voltage, which is configured to control the conversion transistor to generate the supply voltage.

In one preferred embodiment, during transitions to the enabled state and the disabled state, the first gate voltage is delayed relative to the second gate voltage by a time difference.

The objectives, technical details, features, and effects of the present invention will be better understood with regard to the detailed description of the embodiments below, with reference to the attached drawings.

### BRIEF DESCRIPTION OF THE DRAWINGS

FIGS. 1A and 1B show schematic diagrams illustrating prior art switching circuits.

FIG. 2 show a cross-sectional schematic diagram of a junction field-effect transistor (JFET) according to an embodiment of the present invention.

FIG. 3 shows a schematic diagram of a switching circuit according to an embodiment of the present invention.

FIG. 4A shows a schematic diagram of a switching circuit according to an embodiment of the present invention.

FIG. 4B shows a schematic diagram of a switching circuit according to another embodiment of the present invention.

FIG. 5 shows a schematic diagram showing the operational waveforms corresponding to the switching circuit according to an embodiment of the present invention.

FIG. 6A shows a schematic diagram of a switching circuit according to yet another embodiment of the present invention.

FIG. 6B shows a schematic diagram of a switching circuit according to yet another embodiment of the present invention.

FIG. 7A shows a schematic diagram of a switching circuit according to still another embodiment of the present invention.

FIG. 7B shows a schematic diagram of a switching circuit according to another embodiment of the present invention.

FIG. 7C shows a schematic diagram of a switching circuit according to yet another embodiment of the present invention.

FIG. 8 shows a schematic diagram of a switching circuit according to another embodiment of the present invention.

FIG. 9 shows a schematic diagram of a switching circuit according to yet another embodiment of the present invention.

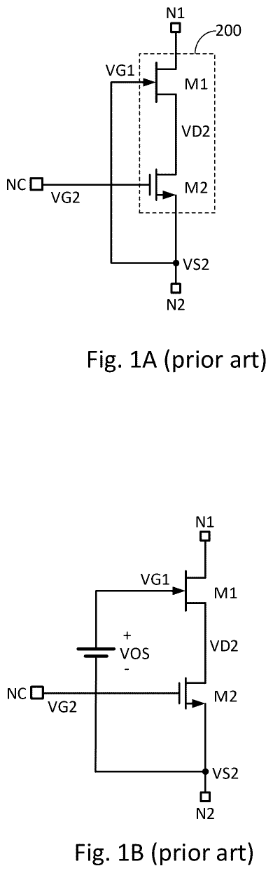

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

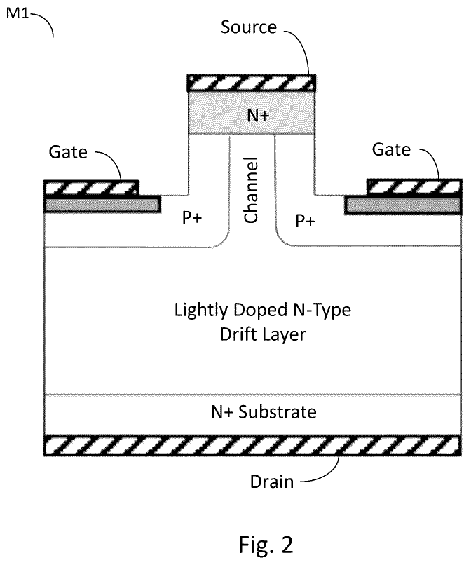

FIG. 2 illustrates a cross-sectional diagram of a compound junction field-effect transistor (JFET) M1. The compound JFET M1 may, for example, be a silicon carbide (SiC) JFET. As shown in FIG. 2, a PN junction exists between the gate and the source of the JFET. In this structure, the conduction and cut-off states of transistor M1 are controlled by adjusting the gate voltage. When the gate-to-source voltage exceeds a certain threshold, transistor M1 conducts. Generally, in the case of an N-type transistor, the conduction threshold of a silicon carbide JFET is less than 0, meaning that the transistor M1 is preset to conduct when the gate-to-source voltage is 0. The SiC transistor M1 shown in FIG. 2 features high breakdown voltage and high thermal conductivity, making it suitable for high-voltage, high-temperature applications.

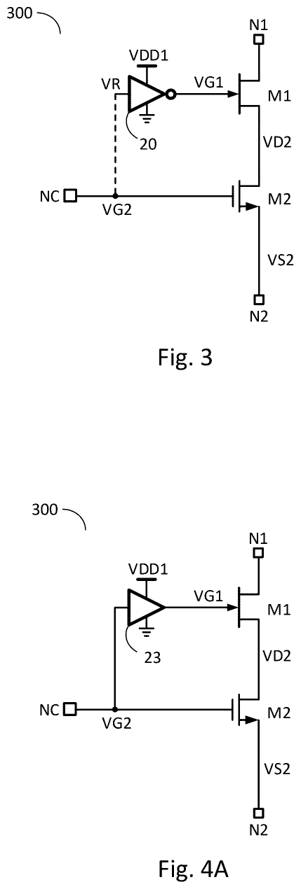

FIG. 3 depicts an embodiment of a switching circuit according to the present invention. In this embodiment, switching circuit 300 includes a JFET M1 and an enhancement-mode MOSFET M2 connected in series between a first terminal N1 and a second terminal N2 of the circuit. In one embodiment, the second terminal N2 may, for example, be coupled to a ground potential. This embodiment further includes a level-shifting circuit 20 to control the switching operations of transistors M1 and M2. The level-shifting circuit 20 generates the gate voltage VG1 of transistor M1 based on a pre-control voltage VR associated with the gate voltage VG2 of transistor M2. Various embodiments of the level-shifting circuit 20 and the pre-control voltage VR will be described later.

It is worth noting that in the switching circuit 300 shown in FIG. 3, the SiC JFET M1 withstands the high voltage across the circuit during the off-state of the switching circuit 300 in high-voltage applications. In contrast, the enhancement-mode MOSFET M2 is not subjected to high voltage in either its on-state or off-state. Consequently, the transistor M2 can be implemented using an enhancement-mode MOSFET with a much lower voltage rating than the SiC JFET M1, thereby reducing costs.

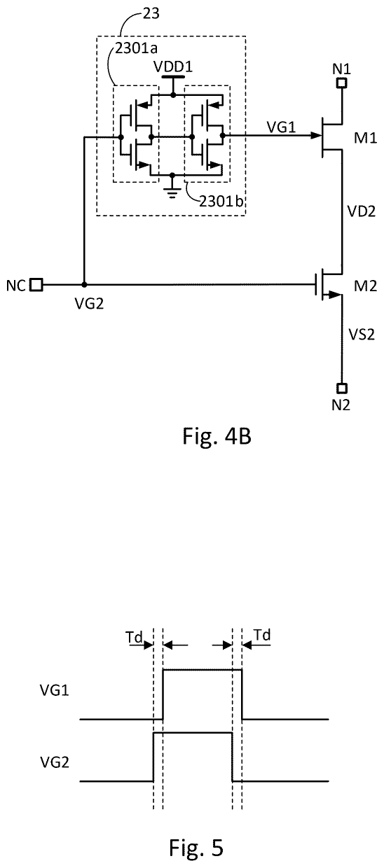

FIG. 4A shows a specific embodiment of the switching circuit 300. In this embodiment, the level-shifting circuit 23 is controlled by the gate voltage VG2 of transistor M2 to generate the gate voltage VG1 of transistor M1. The high-level enable state of VG1 is determined by a supply voltage VDD1.

FIG. 4B presents a more specific embodiment of the switching circuit corresponding to FIG. 4A. In this embodiment, the level-shifting circuit 23 acts as a buffer and comprises two cascaded inverters, 2301a and 2301b. These inverters are powered by a stable supply voltage VDD1, which is approximately 1V to 2V. Specifically, the level-shifting circuit 23 performs voltage shifting. When VG2 of transistor M2 is at a high voltage level (e.g., 5V), VG1 is shifted up to VDD1. This ensures that JFET M1 conducts without entering a forward bias state and achieves a low on-resistance.

It should be noted that in this embodiment, both M1 and M2 are N-type transistors. VG2 at a high level corresponds to the enabled state of M2. When VG1 is at the high level (e.g., VDD1), it ensures that M1 is in a state of reduced on-resistance, thereby lowering the equivalent resistance of the circuit. In one embodiment, the supply voltage VDD1 is less than the gate-to-source forward conduction voltage Vf_M1 of M1 (i.e., VDD1<Vf_M1) to prevent the gate-to-source junction of the JFET M1 from entering a forward bias state.

FIG. 5 illustrates operational waveforms corresponding to the switching circuit of the present invention. As shown in FIG. 5, due to the delay effect of the buffer, the timing of turn-on and turn-off of the JFET M1 is slightly delayed by a time difference Td compared to transistor M2.

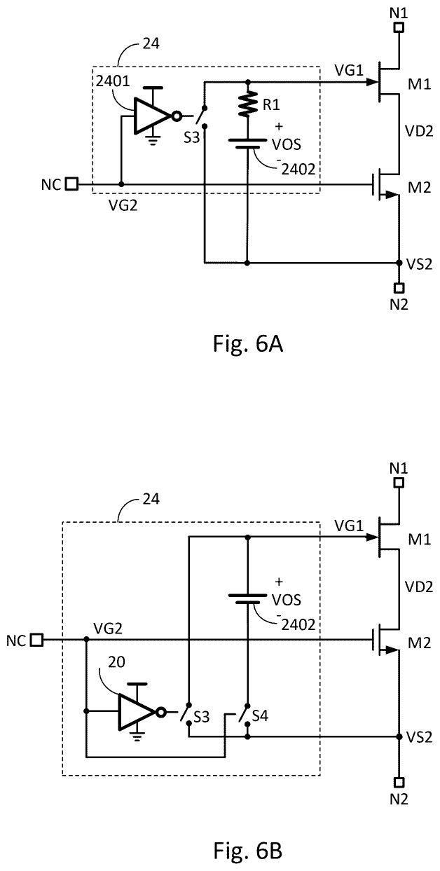

FIGS. 6A and 6B show two embodiments of the switching circuit of the present invention. The level-shifting circuit 24 includes an inverter 2401, a switch S3, a RV source 2402 with a level-shift voltage VOS and a resistor R1, which are configured to control VG1 based on the state of VG2. In FIG. 6A, inverter 2401 receives VG2 from transistor M2 to control the switch S3. The switch S3 is connected between the gate of the transistor M1 and the source of M2. The RV source 2402 and resistor R1 are connected in series between the gate of M1 and the source of M2. When the gate voltage VG2 of the transistor M2 is in the enabled state, the inverter 2401 turns off the switch S3, causing the gate voltage VG1 equals the source voltage VS2 plus the VOS, thereby reducing on-resistance of the transistor M1.

The embodiment in FIG. 6B is similar to FIG. 6A, with the difference that RV source 2402 and the resistor R1 are replaced with a RV source 2402 and a switch S4. Switches S3 and S4 operate inversely. When the gate voltage VG2 is high, the switch S3 turns off, the switch S4 turns on, causing the gate voltage VG1 equals the source voltage VS2 plus VOS. When the gate voltage VG2 is low, the switch S3 turns on, the switch S4 turns off, and the gate voltage VG1 is pulled down to be equal to the source voltage VS2.

In one embodiment, the level-shift voltage VOS is less than the gate-to-source forward conduction voltage Vf_M1 of the first transistor M1, i.e., VOS<Vf_M1, ensuring that the gate-to-source voltage of the first transistor M1 does not enter a forward bias state.

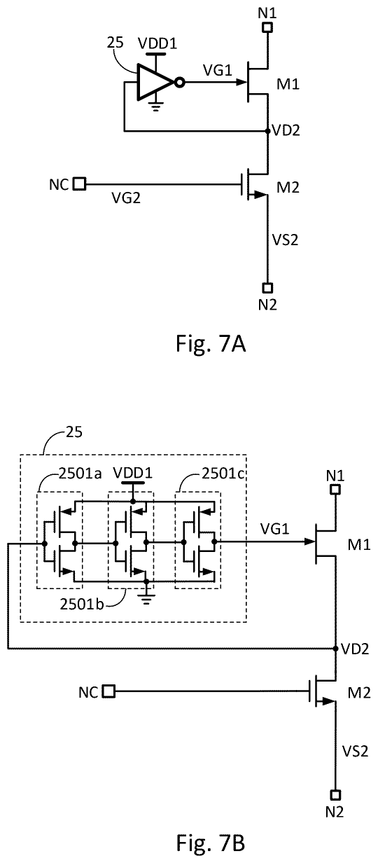

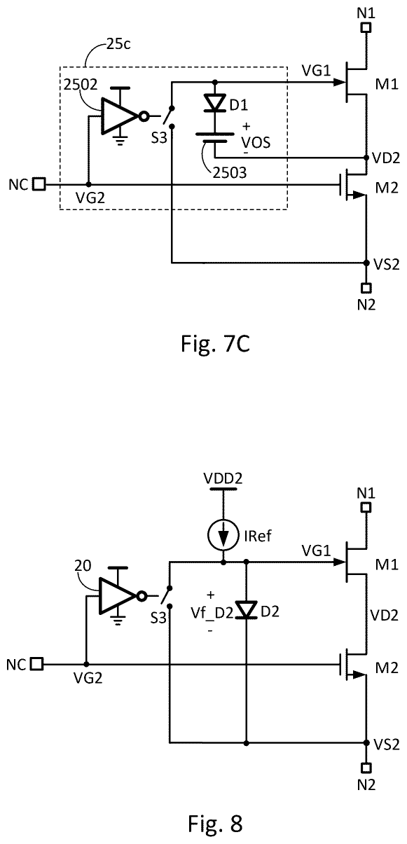

FIGS. 7A, 7B, and 7C illustrate three embodiments of the switching circuit according to the present invention. The embodiment shown in FIG. 7A is similar to the embodiment shown in FIG. 4A, with the difference being that the level-shifting circuit 25 in this embodiment corresponds to an inverted level-shifting circuit. This level-shifting circuit generates the gate voltage VG1 of the first transistor M1 based on the drain voltage VD2 of the second transistor M2. Since the drain voltage VD2 also responds to the gate voltage VG2 of the second transistor M2, the gate voltage VG1 of the first transistor M1 and the gate voltage VG2 of the second transistor M2 are indirectly linked. Similarly, the enabled level of the gate voltage VG1 is determined by the supply voltage VDD1.

FIG. 7B shows a specific embodiment corresponding to FIG. 7A. In this embodiment, the circuit includes an odd number of inverters, specifically inverters 2501a, 2501b, and 2501c. When multiple inverters are used, they are cascaded, and each inverter is powered by the supply voltage VDD1.

FIG. 7C illustrates an embodiment combining different concepts previously mentioned, wherein the gate voltage VG1 of the first transistor M1 is controlled based on either the drain voltage VD2 or the source voltage VS2 of the second transistor M2, resulting in different voltage states. The level-shifting circuit 25C includes an inverter 2502, a switch S3, a RV source 2503, and a diode D1. The RV source 2503 and the diode D1 are connected in series between the gate of the first transistor M1 and the drain of the second transistor M2. When the gate voltage VG2 of the second transistor M2 is in the enabled state, the inverter 2502 controls the switch S3 to be turned off. Thus, the gate voltage VG1 is equal to the sum of the level-shift voltage VOS and the drain voltage VD2, thereby reducing the on-resistance of the first transistor M1. Conversely, when the gate voltage VG2 of the second transistor M2 is in the disabled state, the inverter 2502 controls the switch S3 to be turned on, electrically connecting the gate voltage VG1 to the source voltage VS2 of the second transistor M2.

FIG. 8 shows another specific embodiment of the switching circuit according to the present invention. This embodiment is similar to the embodiment in FIG. 6A, with the difference being that in this embodiment, the enabled level of the gate voltage VG1 of the first transistor M1 is controlled by a current source IRef and a forward-connected diode D2. This configuration ensures that the gate voltage VG1 in the enabled state is higher than the source voltage VS2 of the second transistor M2 by the forward voltage Vf_D2 of the diode D2. In one embodiment, the forward voltage Vf_D2 corresponds to the aforementioned level-shift voltage VOS. In this embodiment, the current source IRef may be coupled between the supply voltage VDD2 and the gate voltage VG1. The supply voltage VDD2 is higher than the forward voltage Vf_D2.

It is worth mentioning that the level-shift voltage VOS or the supply voltage VDD1 described in the present invention is lower than the gate-to-source forward conduction voltage Vf_M1 of the first transistor M1, i.e., VDD1<Vf_M1 or VOS<Vf_M1. When the gate voltage VG2 of the second transistor M2 is at a high level (enabled state), the gate voltage VG1 of the first transistor M1 will also be raised to the supply voltage VDD1 or the sum of the level-shift voltage VOS and the source voltage VS2 or the drain voltage VD2 of the second transistor M2. This configuration reduces the on-resistance of the first transistor M1. Simultaneously, under the aforementioned constraints, the gate voltage VG1 does not exceed the gate-to-source forward conduction voltage Vf_M1 of the first transistor M1, thus avoiding a forward bias state at the gate-to-source junction of the first transistor M1.

Furthermore, it is worth emphasizing that since the gate voltage VG1 in the enabled state is only moderately raised, which allows the switching actions of the first transistor M1, including both turning on and turning off, to occur slightly later than those of the second transistor M2 (as shown in FIG. 5), without requiring more complex timing control. Consequently, the level-shifting circuit in the present invention can directly employ a buffer or inverter as previously described.

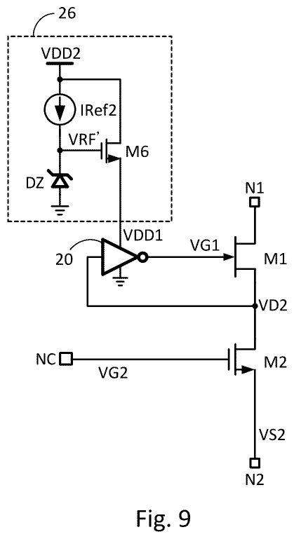

FIG. 9 illustrates a more specific embodiment corresponding to FIG. 7A. In this embodiment, the switching circuit further includes a low-dropout regulator (LDO) 26, which converts the supply voltage VDD2 into the supply voltage VDD1. The low-dropout regulator 26 generates a pre-regulated pre-control voltage VRF′ using a current source IRef2 and a Zener diode DZ. A conversion transistor M6, connected as a source-follower configuration, buffers the pre-regulated pre-control voltage VRF′ and converts the supply voltage VDD2 to output a stable supply voltage VDD1 in the range of 1V to 2V. This supply voltage VDD1 powers the inverter 20 in FIG. 9 or the inverters and buffers in FIGS. 3, 4A, 4B, 7A, and 7B.

The various embodiments described above provide detailed illustrations of how the level-shifting circuit of the present invention precisely controls the gate voltage VG1 of the first transistor M1, effectively reducing the on-resistance of the switching circuit. Additionally, the present invention prevents the PN junction of the first transistor M1 from entering a forward bias state, reduces the complexity of timing control, and enhances both the performance and cost efficiency of the switching circuit.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A switching circuit comprising:
a first transistor, which is a compound junction transistor;
a second transistor, which is an enhancement-mode MOS transistor;
the first transistor and the second transistor being connected in series between a first terminal and a second terminal of the switching circuit, for controlling conduction and cutoff between the first terminal and the second terminal;
a first gate voltage for controlling a gate of the first transistor;
a second gate voltage for controlling a gate of the second transistor; and
a level-shifting circuit for generating the first gate voltage based on a pre-control voltage associated with the second gate voltage.

2. The switching circuit of claim 1, wherein a breakdown voltage of the first transistor is higher than a breakdown voltage of the second transistor.

3. The switching circuit of claim 1, configured in one of the following arrangements:
arrangement A: when the second gate voltage is controlled to an enabled state, the level-shifting circuit shifts the pre-control voltage by a level-shift voltage to generate the first gate voltage; or
arrangement B: when the second gate voltage is controlled to an enabled state, the level-shifting circuit switches the first gate voltage to a supply voltage based on the pre-control voltage, wherein the supply voltage is higher than a source voltage of the second transistor.

4. The switching circuit of claim 3, wherein, in arrangement A:
the pre-control voltage corresponds to the source voltage of the second transistor, wherein the first gate voltage equals the source voltage of the second transistor plus the level-shift voltage; or
the pre-control voltage corresponds to a drain voltage of the second transistor, wherein the first gate voltage equals the drain voltage plus the level-shift voltage.

5. The switching circuit of claim 3, wherein, in arrangement B:
the pre-control voltage corresponds to the second gate voltage or to a drain voltage of the second transistor.

6. The switching circuit of claim 1, wherein, in an enabled state, the level of the second gate voltage is higher than the level of the first gate voltage.

7. The switching circuit of claim 3, wherein:
in arrangement A, in the enabled state, a level of the level-shift voltage is lower than a gate-to-source forward conduction voltage of the first transistor; or
in arrangement B, the supply voltage is less than the gate-to-source forward conduction voltage of the first transistor.

8. The switching circuit of claim 1, wherein the first transistor is a silicon carbide junction field-effect transistor (SiC JFET).

9. The switching circuit of claim 1, wherein the first transistor and the second transistor are both N-type or both P-type transistors.

10. The switching circuit of claim 3, wherein, in arrangement A, the level-shifting circuit further includes:
a first adjustment switch coupled between the source voltage of the second transistor and the first gate voltage, configured to switch based on the second gate voltage, wherein the first adjustment switch is off when the second gate voltage is in the enabled state and is on when the second gate voltage is in a disabled state.

11. The switching circuit of claim 10, wherein, in arrangement A, the level-shifting circuit further includes:
a RV source and a resistor connected in series between the source voltage of the second transistor and the first gate voltage;
the RV source and a second adjustment switch connected in series between the source voltage of the second transistor and the first gate voltage, wherein the second adjustment switch operates inversely to the first adjustment switch;
the RV source and a first diode connected in series between the source voltage of the second transistor and the first gate voltage; or
a second diode biased by a current source and coupled between the source voltage of the second transistor and the first gate voltage;
wherein the RV source provides the level-shift voltage, or the forward conduction voltage of the second diode corresponds to the level-shift voltage.

12. The switching circuit of claim 3, further comprising:
a Zener diode and a conversion transistor, wherein the Zener diode provides a pre-reference voltage, which is configured to control the conversion transistor to generate the supply voltage.

13. The switching circuit of claim 1, wherein, during transitions to the enabled state and the disabled state, the first gate voltage is delayed relative to the second gate voltage by a time difference.
